(19) United States
(12) Patent Application Publication
(10) Pub. No.: US 2025/0080075 A1
(43) Pub. Date: Mar. 6, 2025

(54) N-PATH FILTER

(71) Applicant: Murata Manufacturing Co., Ltd., Nagaokakyo-shi (JP)

(72) Inventor: Hajime KANDO, Nagaokakyo-shi (JP)

(21) Appl. No.: 18/953,206

(22) Filed: Nov. 20, 2024

Related U.S. Application Data
(63) Continuation of application No. PCT/JP2023/020447, filed on Jun. 1, 2023.

(30) Foreign Application Priority Data
Jun. 10, 2022 (JP) 2022-094272

(51) Int. Cl. H03H 7/01; H03H 9/56

(52) U.S. Cl. CPC H03H 7/0115; H03H 9/568

(57) ABSTRACT

An N-path filter includes N-number signal paths connected in parallel to each other between first and second input-output terminals. Each N-number signal path includes a first switch connected to the first input-output terminal to modulate an input signal, a second switch connected to the second input-output terminal to modulate the input signal in a same phase as that of the switch, and a base filter connected between the first and second switches. The first and second switches are operable to modulate the input signal in a phase of one period including different phases of the different signal paths. The base filter is a band pass filter including only passive elements.

### CROSS REFERENCE TO RELATED APPLICATIONS

This application claims the benefit of priority to Japanese Patent Application No. 2022-094272 filed on Jun. 10, 2022 and is a Continuation Application of PCT Application No. PCT/JP2023/020447 filed on Jun. 1, 2023. The entire contents of each application are hereby incorporated herein by reference.

### BACKGROUND OF THE INVENTION

### 1. Field of the Invention

The present invention relates to N-path filters.

### 2. Description of the Related Art

Japanese Unexamined Patent Application Publication No. 4-56524 discloses a variable frequency N-path filter. The N-path filter includes N-number base filters disposed between an input terminal and an output terminal and a mixer connected to both ends of the N-number base filters. With this configuration, the N-path filter is a variable passband filter and is usable as a tunable filter used in a single superheterodyne receiver in a tuner circuit that receives a television signal and a cable television signal.

However, in the N-path filter described in Japanese Unexamined Patent Application Publication No. 4-56524, the base filters are each composed of an active element, such as an operational amplifier. Accordingly, when the N-path filter is applied to a radio frequency (RF) stage of a mobile phone, problems including loss increase within the passband caused by non-linear characteristics of the active elements and insufficient attenuation outside the passband occur, for example, in a high frequency area of 500 MHz or more.

### SUMMARY OF THE INVENTION

Example embodiments of the present invention provide N-path filters each with low loss within the passband and high attenuation outside the passband in a high frequency area.

An N-path filter according to an example embodiment of the present invention includes a first input-output terminal and a second input-output terminal, and N-number signal paths connected in parallel to each other between the first input-output terminal and the second input-output terminal, N being an integer not less than three. Each of the N-number signal paths includes a first modulator connected to the first input-output terminal to modulate an input signal supplied from the first input-output terminal or the second input-output terminal, a second modulator connected to the second input-output terminal to modulate the input signal in a same phase as that of the first modulator, and a base filter connected between the first modulator and the second modulator. The first modulator and the second modulator are operable to modulate the input signal in a phase of one period including different phases of the different N-number signal paths. The base filter is a band pass filter including only passive elements.

According to example embodiments of the present invention, it is possible to provide N-path filters each with low loss within the passband and high attenuation outside the passband in a high frequency area.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a diagram illustrating the circuit configuration of an N-path filter according to an example embodiment of the present invention.

FIG. 2 is a timing chart indicating driving signals of an N-path filter according to an example embodiment of the present invention.

FIG. 3 is a diagram illustrating an example of a circuit configuration of a base filter according to a first example.

FIG. 4A is a graph indicating a bandpass characteristic near a passband of the single base filter according to the first example.

FIG. 4B is a graph indicating a bandpass characteristic in a wide band including an attenuation band of the single base filter according to the first example.

FIG. 5 is a graph indicating an example of a bandpass characteristic of the N-path filter according to the first example.

FIG. 6 is a graph indicating bandpass characteristics when a driving frequency Fck of the N-path filter according to the first example is varied.

FIG. 7 is a diagram illustrating an example of the circuit configuration of a base filter according to a second example.

FIG. 8A is a graph indicating resonance characteristics of the base filter according to the second example.

FIG. 8B is a graph indicating a bandpass characteristic near the passband of the single base filter according to the second example.

FIG. 8C is a graph resulting from comparison between the bandpass characteristics of the base filters according to the first and second examples.

FIG. 9 is a graph indicating bandpass characteristics when the driving frequency Fck of the N-path filter according to the second example is varied.

FIG. 10 is a diagram illustrating an example of a circuit configuration of a base filter according to a third example.

FIG. 11A is a graph indicating a bandpass characteristic near the passband of the single base filter according to the third example and FIG. 11B is a graph indicating a bandpass characteristic near the passband of the single base filter according to the second example.

FIG. 12 is a graph indicating bandpass characteristics when the driving frequency Fck of the N-path filter according to the third example is varied.

FIG. 13 is a graph indicating a variable frequency range when a main response mode of an N-path filter according to an example embodiment of the present invention is (Fck−Fb).

FIG. 14 is a graph indicating a variable frequency range when a main response mode of an N-path filter according to an example embodiment of the present invention is (−Fck+Fb).

FIG. 15 is a graph indicating a variable frequency range when a main response mode of an N-path filter according to an example embodiment of the present invention is (2Fck−Fb).

FIG. 16 is a graph indicating a variable frequency range when a main response mode of an N-path filter according to an example embodiment of the present invention is (Fck+Fb).

FIG. 17 is a diagram illustrating a circuit configuration of a radio frequency module and a communication apparatus according to an example embodiment of the present invention.

### DETAILED DESCRIPTION OF THE EXAMPLE EMBODIMENTS

Example embodiments of the present invention will herein be described in detail with reference to the drawings. All of the example embodiments described below indicate comprehensive or specific examples. Numerical values, shapes, materials, components, the arrangement of the components, the connection mode of the components, and so on, which are indicated in the example embodiments described below, are only examples and are not intended to limit the present invention. Among components in the example embodiments described below, the components that are not described in the independent claim are described as arbitrary components. The sizes or the ratios of the sizes of the components in the drawings are not necessarily strictly illustrated.

In the example embodiments described below, the passband of a filter is defined as a frequency band between two frequencies that are about 3 dB higher than the minimum value of insertion loss within the passband unless otherwise specified. The center frequency of a filter is defined as a midpoint of a low-end frequency and a high-end frequency (the low-end-frequency+the high-end frequency)/2) of the passband of the filter.

In the example embodiments described below, a “signal path” means a transmission line including wiring through which a radio frequency signal is propagated, circuit elements and electrodes that are directly connected to the wiring, terminals that are directly connected to the wiring or the electrodes, and so on.

In the example embodiments described below, “connected” includes not only direct connection with a connection terminal and/or a wiring conductor but also electrical connection via another circuit element. “Connected between A and B” means connection to A and B on a path between A and B.

### Example Embodiments

### 1. Circuit Configuration of N-Path F2

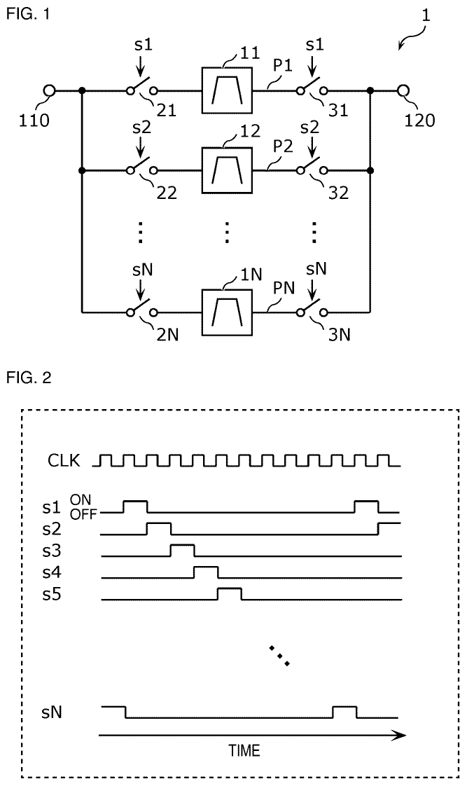

FIG. 1 is a diagram illustrating a circuit configuration of an N-path filter 1 according to an example embodiment of the present invention. As illustrated in FIG. 1, the N-path filter 1 includes base filters 11 to 1N (N is an integer not less than three), switches 21 to 2N (N is an integer not less than three) and switches 31 to 3N (N is an integer not less than three), an input-output terminal 110 (a first input-output terminal), and an input-output terminal 120 (a second input-output terminal).

The switch 21 is an example of a first switch and is connected to the input-output terminal 110 and the base filter 11. The switch 21 performs on-off operations in response to a driving signal s1 based on a driving frequency Fck to switch between connection and non-connection between the input-output terminal 110 and the base filter 11.

The switch 31 is an example of a second switch and is connected to the input-output terminal 120 and the base filter 11. The switch 31 performs on-off operations at the same timing as that of the switch 21 in response to the driving signal s1 based on the driving frequency Fck to switch between connection and non-connection between the input-output terminal 120 and the base filter 11.

The switch 22 is an example of the first switch and is connected to the input-output terminal 110 and the base filter 12. The switch 22 performs on-off operations in response to a driving signal s2 based on the driving frequency Fck to switch between connection and non-connection between the input-output terminal 110 and the base filter 12.

The switch 32 is an example of the second switch and is connected to the input-output terminal 120 and the base filter 12. The switch 32 performs on-off operations at the same timing as that of the switch 22 in response to the driving signal s2 based on the driving frequency Fck to switch between connection and non-connection between the input-output terminal 120 and the base filter 12.

The switch 2N is an example of the first switch and is connected to the input-output terminal 110 and the base filter 1N. The switch 2N performs on-off operations in response to a driving signal sN based on the driving frequency Fck to switch between connection and non-connection between the input-output terminal 110 and the base filter 1N.

The switch 3N is an example of the second switch and is connected to the input-output terminal 120 and the base filter 1N. The switch 3N performs on-off operations at the same timing as that of the switch 2N in response to the driving signal sN based on the driving frequency Fck to switch between connection and non-connection between the input-output terminal 120 and the base filter 1N.

The base filter 11 and the switches 21 and 31 define a signal path P1. The base filter 12 and the switches 22 and 32 define a signal path P2. The base filter 1N and the switches 2N and 3N define a signal path PN (N is an integer not less than three).

The N-path filter 1 includes N-number signal paths including the signal paths P1, P2, and PN. The signal paths Pl to PN are connected in parallel to each other between the input-output terminal 110 and the input-output terminal 120.

The base filter 11 is connected between the switches 21 and 31 and is a band pass filter including only passive elements. The base filter 12 is connected between the switches 22 and 32 and is a band pass filter including only passive elements. The base filter 1N is connected between the switches 2N and 3N and is a band pass filter including only passive elements. The circuit configuration of the base filters 11 to 1N will be exemplified in detail in first to third examples.

FIG. 2 is a timing chart indicating the driving signals of the N-path filter 1 according to the present example embodiment. An example of the driving signals s1 to sN supplied to the switches 21 to 2N and the switches 31 to 3N, respectively, is indicated in FIG. 2. As indicated in FIG. 2, the driving signals s1 to sN are generated based on a clock signal CLK (the driving frequency Fck). More specifically, when the period of the driving signals s1 to sN is denoted by T, the respective driving signals s1 to sN are in an on state only during a period of T/N and are sequentially in the on state with a delay of T/N. Accordingly, the switches 21 to 2N are in the on state at different timings for the respective signal paths with the period T. The switches 31 to 3N are in the on state at different timings for the respective signal paths with the period T. In other words, the base filters 11 to 1N are connected to the input-output terminals 110 and 120 at different timings for the respective signal paths with the period T.

With the above configuration, the N-path filter 1 is a band pass filter having a center frequency Frf specified by Equation 1:

Frf=k×Fck±Fb (Equation 1)

In Equation 1, Fb denotes the center frequency of the base filter and k is an integer. According to Equation 1, the N-path filter 1 varies the driving frequency Fck to serve as a variable passband band pass filter. Bandpass characteristics of the N-path filter 1 include multiple passbands (and multiple attenuation bands) corresponding to the value of k (an integer from −∞ to +∞).

The N-path filter 1 according to the present example embodiment is not limited to the operation in response to the driving signals s1 to sN indicated in FIG. 2. Each of the driving signals s1 to sN is not necessarily in the on state only during the period of T/N and the period during which each of the driving signals s1 to sN is in the on state may be shorter or longer than T/N. In other words, the periods during which the respective driving signals s1 to sN are in the on state are not strictly continuous and may be slightly separated. In addition, (the lengths of) the periods during which the respective driving signals s1 to sN are in the on state are not necessarily equal to each other and may be different from each other.

Since the base filters 11 to 1N include only the passive elements in the above configuration of the N-path filter 1, saturation and non-linear distortion, which are caused by semiconductor elements, are capable of being reduced or prevented, compared with a case in which each of the base filters includes active elements including the semiconductor elements. Accordingly, it is possible to obtain the N-path filter 1 having low loss within the passband and high attenuation outside the passband in a high frequency area of, for example, about 500 MHz or more, which is used for an RF stage of a mobile phone.

In the N-path filter 1 according to the present example embodiment, each of the switches 21 to 2N may be a first modulator that modulates an input signal input through the input-output terminal 110 or 120. Each of the switches 31 to 3N may be a second modulator that modulates the input signal input through the input-output terminal 110 or 120 in the same phase as that of the first modulator. Specifically, each of the first modulator and the second modulator modulates the input signal input through the input-output terminal 110 or 120 in a phase of one period composed of different phases of the different N-number signal paths. Although each of the switches 21 to 2N is an example of the first modulator and each of the switches 31 to 3N is an example of the second modulator, for example, mixers may be used as the first modulator and the second modulator, instead of the switches 21 to 2N and the switches 31 to 3N.

### 2. Circuit Configuration and Bandpass Characteristics of Base Filters 11 to 1N According to First Example

The N-path filter 1 according to a first example includes the base filters 11 to 1N (N is an integer not less than three), the switches 21 to 2N (N is an integer not less than three) and the switches 31 to 3N (N is an integer not less than three), and the input-output terminals 110 and 120.

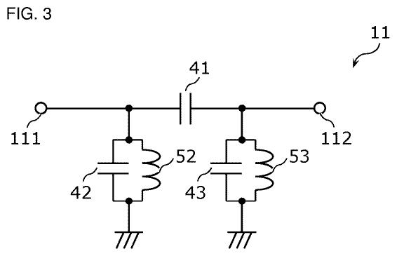

FIG. 3 is a diagram illustrating an example of the circuit configurations of the base filters 11 to 1N according to the first example. An example of the circuit configuration of the base filter 11, among the base filters 11 to 1N, is illustrated in FIG. 3. The circuit configurations of the base filters 12 to 1N are the same or substantially the same as the circuit configuration of the base filter 11 illustrated in FIG. 3.

As illustrated in FIG. 3, the base filter 11 includes capacitors 41, 42, and 43 and inductors 52 and 53. Each of the base filters 11 to 1N according to the present example is a band pass filter including only the passive elements and includes the inductors and the capacitors.

One end of the capacitor 41 is connected to a terminal 111 and the other end thereof is connected a terminal 112. An LC parallel resonant circuit including the capacitor 42 and the inductor 52 is connected between a node on a path between the terminal 111 and the capacitor 41 and ground. An LC parallel resonant circuit including the capacitor 43 and the inductor 53 is connected between a node on a path between the terminal 112 and the capacitor 41 and the ground. With the above configuration, the base filter 11 illustrated in FIG. 3 defines a n-type three-stage band pass filter. The configuration in which the two LC parallel resonant circuits are connected with the capacitor 41 without using a series inductor is provided. Since the maximum inductor values of the inductors 52 and 53 are decreased to a low value of, for example, about 0.63 nH in this configuration, it is possible to reduce the size of the base filter 11.

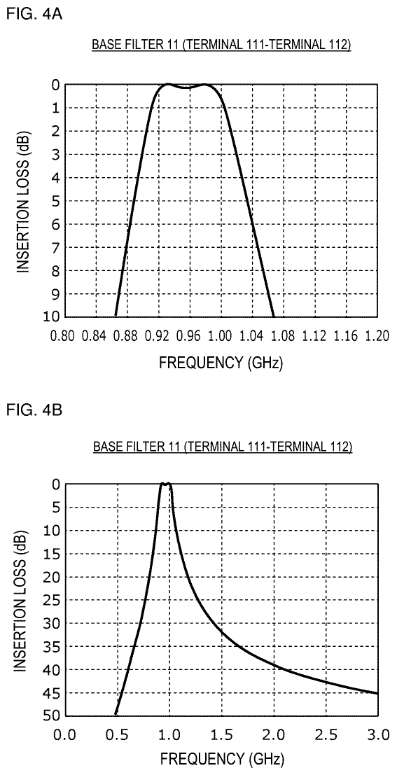

FIG. 4A is a graph indicating a bandpass characteristic near the passband of the single base filter 11 according to the first example. FIG. 4B is a graph indicating a bandpass characteristic in a wide band including the attenuation band of the single base filter 11 according to the first example. As indicated in FIGS. 4A and 4B, for example, the base filter 11 is a band pass filter having a center frequency of about 960 MHz and a band width of about 120 MHz.

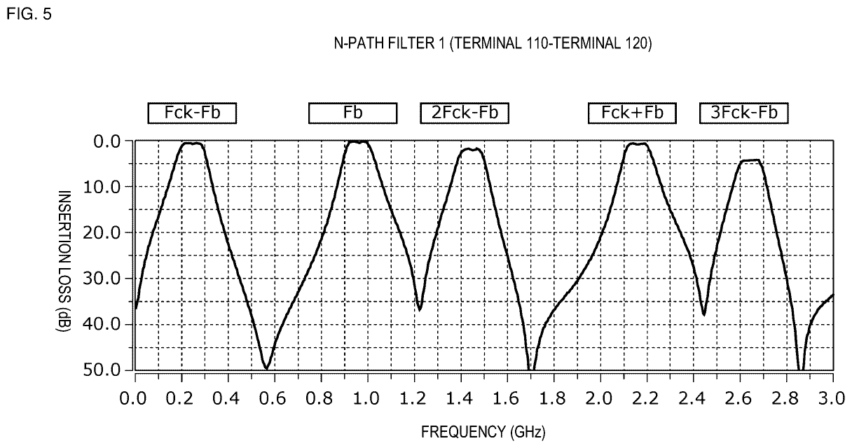

FIG. 5 is a graph indicating an example of a bandpass characteristic of the N-path filter 1 according to the first example. In the N-path filter 1 according to the present example, N=8, the center frequency Fb of the base filter 11=about 979.49 MHz, the driving frequency Fck=about 1,200 MHz, the driving signals s1 to s8 are rectangular pulses having a pulse width=about (1/1,200 MHz)/8, and the terminal impedance of each of the base filters 11 to 1N is set to about 400 Ω. In other words, the terminal impedance of the N-path filter 1 is, for example, set to about 50 Ω.

As indicated in FIG. 5, the passband of the N-path filter 1 appears at (Fck−Fb) (k=1), Fb (k=0), (2Fck−Fb) (k=2), (Fck+Fb) (k=1), and (3Fck−Fb) (k=3) in a frequency band range from Direct Current (DC) to 3 GHz. Since the terminal impedance of the base filters 11 to 1N is set to, for example, about 400 Ω and the terminal impedance of the N-path filter 1 is set to, for example, about 50 Ω, the respective passbands of the N-path filter 1 have flat bandpass characteristics.

In the N-path filter 1 according to the present example, when the terminal impedance at the input-output terminals 110 and 120 is denoted by Z₀ and the input-output impedance of the base filters 11 to 1N is denoted by Zb, a reflection coefficient (Zb−N×Z₀)/(Zb+N×Z₀) desirably meets the relationship of Expression 2:

(Zb−N×Z₀)/(Zb+N×Z₀)<0.316 Expression 2

Since the terminal impedance at the terminals 111 and 112 of the base filters 11 to 1N is designed to be, for example, about 400 Ω in the N-path filter 1 according to the present example, the reflection coefficient is ideally zero (0) when Z₀=50 Ω, Zb=400 Ω, and N=8 are substituted into Expression 2.

Since the active elements are used as the base filters in an N-path filter in related art, the N-path filter has large impedance and the terminal impedance of the N-path filter is frequently assumed to be substantially opened. Accordingly, mismatching loss with an external connection circuit is increased in a high frequency band of about 500 MHz or more.

In contrast, since the return loss at the input-output terminals 110 and 120 is capable of being set to a value of, for example, less than about 10 dB in the N-path filter 1 according to the present example, the mismatching loss with the external connection circuit connected to the input-output terminals 110 or 120 is capable of being reduced or prevented. Accordingly, the N-path filter 1 is applicable to a radio frequency front-end circuit that transmits a radio frequency signal with low loss.

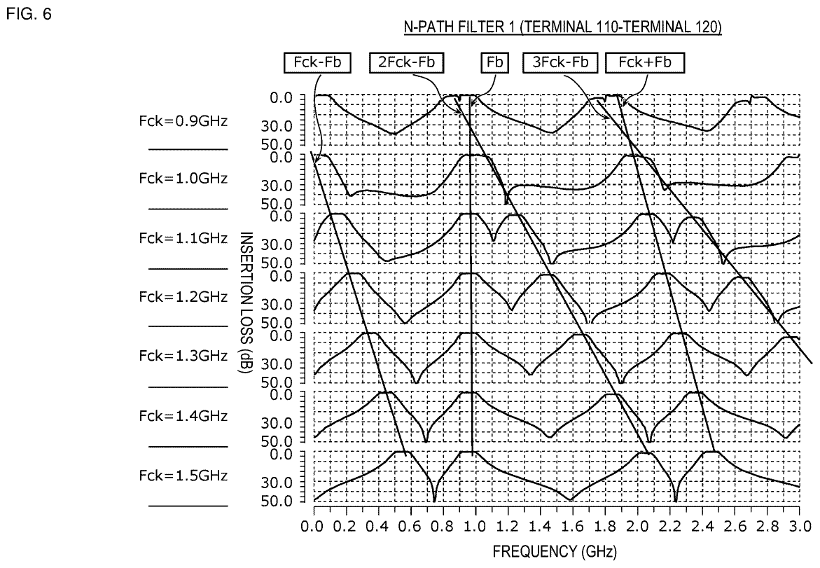

FIG. 6 is a graph indicating bandpass characteristics when the driving frequency Fck of the N-path filter 1 according to the first example is varied. The driving frequency Fck is varied within a range from about 0.9 GHZ to about 1.5 GHZ. As indicated in FIG. 6, since the center frequency Fb (for example, about 979.49 MHz) of the base filters 11 to 1N is close to the driving frequency Fck (for example, about 0.9 GHZ to about 1.5 GHZ), harmonic responses (the respective response modes) are likely to be overlapped with each other. Although the waveforms of the bandpass characteristics are deformed if the harmonic responses are overlapped with each other or are close to each other, drastic loss degradation does not occur.

Since the LC band pass filters are used as the base filters 11 to 1N in the N-path filter 1 according to the present example, it is possible to achieve the low-loss bandpass characteristics having large attenuation and reduced broadened waveform in a variable frequency range of the driving frequency Fck described below.

Since the base filters 11 to 1N according to the present example each include the capacitors and the inductors, which are passive elements, the saturation and the distortion, which are caused by the non-linear characteristics, do not occur even if, for example, a transmission signal is reflected from an antenna and an undesirable signal is input into a reception circuit, compared with the N-path filter including the base filters using the active elements. Accordingly, the N-path filter 1 having sufficient attenuation characteristics is realized.

### 3. Circuit Configuration and Bandpass Characteristics of Base Filters 11A to 1NA According to Second Example

An N-path filter 1A according to a second example includes base filters 11A to 1NA (N is an integer not less than three), the switches 21 to 2N (N is an integer not less than three) and the switches 31 to 3N (N is an integer not less than three), and the input-output terminals 110 and 120.

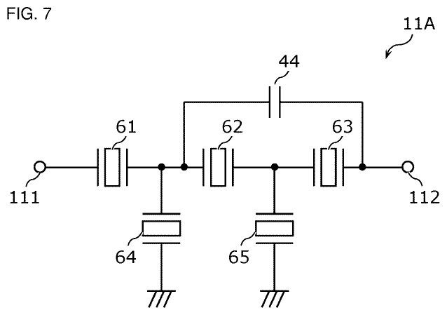

FIG. 7 is a diagram illustrating an example of the circuit configurations of the base filters 11A to 1NA according to the second example. An example of the circuit configuration of the base filter 11A, among the base filters 11A to 1NA, is illustrated in FIG. 7. The circuit configurations of the base filter 12A to 1NA are the same or substantially the same as the circuit configuration of the base filter 11A illustrated in FIG. 7.

As illustrated in FIG. 7, the base filter 11A includes acoustic wave resonators 61, 62, 63, 64, and 65 and a capacitor 44. Each of the base filters 11A to 1NA according to the present example is a band pass filter including only the passive elements and includes the acoustic wave resonators.

The acoustic wave resonators 61 to 63 are series arm resonators connected in series between the terminal 111 and the terminal 112. The acoustic wave resonator 64 is a parallel arm resonator connected between a node on a path between the acoustic wave resonators 61 and 62 and the ground. The acoustic wave resonator 65 is a parallel arm resonator connected between a node on a path between the acoustic wave resonators 62 and 63 and the ground. One end of the capacitor 44 is connected to a node on the path between the acoustic wave resonators 61 and 62 and the other end thereof is connected to the terminal 112. With the above configuration, the base filter 11A illustrated in FIG. 7 is a ladder acoustic-wave band pass filter.

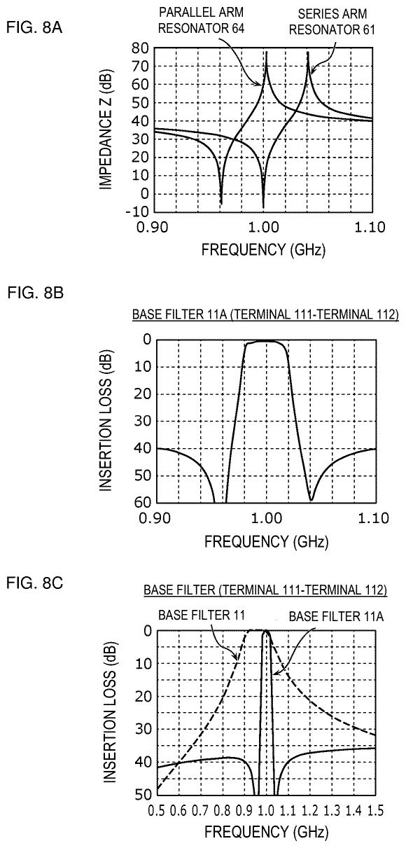

FIG. 8A is a graph indicating resonance characteristics of the base filter 11A according to the second example. In the base filters 11A to 1NA according to the present example, each of the acoustic wave resonators 61 to 65 is a resonator using surface acoustic waves and uses, for example, a 40° rotated Y cut X SAW propagation LiTaO₃ single crystal substrate (hereinafter referred to as LT) as a substrate having piezoelectricity. Each of the acoustic wave resonators 61 to 65 has a resonance band width (anti-resonant frequency−resonant frequency)/resonant frequency) of 4%, and the resonant frequency (and the anti-resonant frequency) of the acoustic wave resonators 61, 63, and 65 is set to a frequency, for example, about 4% higher than the resonant frequency (and the anti-resonant frequency) of the acoustic wave resonators 62 and 64. The impedance of the acoustic wave resonators 61 and 65 is about six times higher than the impedance of the acoustic wave resonators 62 and 64 and the impedance of the acoustic wave resonator 63 is about twelve times higher than the impedance of the acoustic wave resonators 62 and 64. FIG. 8A indicates that the impedance values of the acoustic wave resonators 61 and 64 are equal or substantially equal to each other. In addition, in order to improve attenuation steepness near the passband of the base filters 11A to 1NA, the capacitor 44, which is a bridging capacitance, is provided between the node on the path between the acoustic wave resonators 61 and 62 and the terminal 112. The terminal impedance at the terminals 111 and 112 of the base filters 11A to 1NA is designed to be about 400 Ω.

Also in the N-path filter 1A according to the present example, when the terminal impedance at the input-output terminals 110 and 120 is denoted by Zo and the input-output impedance of the base filters 11A to 1NA is denoted by Zb, the reflection coefficient (Zb−N×Z₀)/(Zb+N×Z₀) desirably meets the relationship of Expression 2.

With the above configuration, since the return loss at the input-output terminals 110 and 120 is capable of being set to a value of, for example, less than about 10 dB, the mismatching loss with the external connection circuit connected to the input-output terminal 110 or 120 is capable of being reduced or prevented. Accordingly, the N-path filter 1A is applicable to a radio frequency front-end circuit that transmits the radio frequency signal with low loss.

FIG. 8B is a graph indicating a bandpass characteristic near the passband of the single base filter 11A according to the second example. FIG. 8C is a graph resulting from comparison between the bandpass characteristics of the base filters according to the first and second examples. As illustrated in FIG. 8B, the base filter 11A is a band pass filter having a center frequency of about 1 GHz and a band width of about 30 MHz. As illustrated in FIG. 8C, since the base filter 11A according to the second example is a surface acoustic wave filter using the LT substrate, the base filter 11A according to the second example has a narrower pass band width and higher attenuation steepness near the passband, compared with those of the base filter 11 according to the first example.

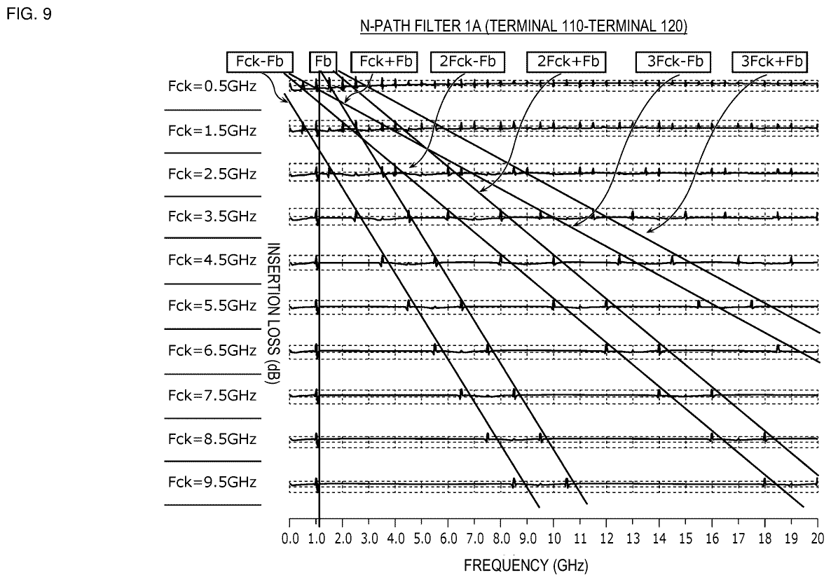

FIG. 9 is a graph indicating bandpass characteristics when the driving frequency Fck of the N-path filter 1A according to the second example is varied. The driving frequency Fck is varied within a range from about 0.5 GHz to about 9.5 GHZ. As illustrated in FIG. 9, the passband of the N-path filter 1A appears at (k×Fck+Fb) (k=1,2, 3) in a frequency band range from DC to about 20 GHZ.

Since the acoustic wave resonators, which are the passive elements, are used as the base filters 11A to 1 NA in the N-path filter 1A according to the present example, it is possible to achieve the low-loss bandpass characteristics having large attenuation and reduced broadened waveform in the variable frequency range of the driving frequency Fck described below.

### 4. Circuit Configuration and Bandpass Characteristics of Base Filters 11B to 1NB According to Third Example

An N-path filter 1B according to a third example includes base filters 11B to 1NB (N is an integer not less than three), the switches 21 to 2N (N is an integer not less than three) and the switches 31 to 3N (N is an integer not less than three), and the input-output terminals 110 and 120.

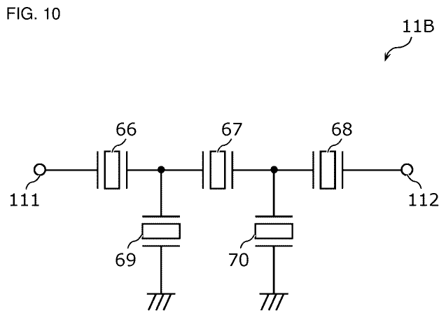

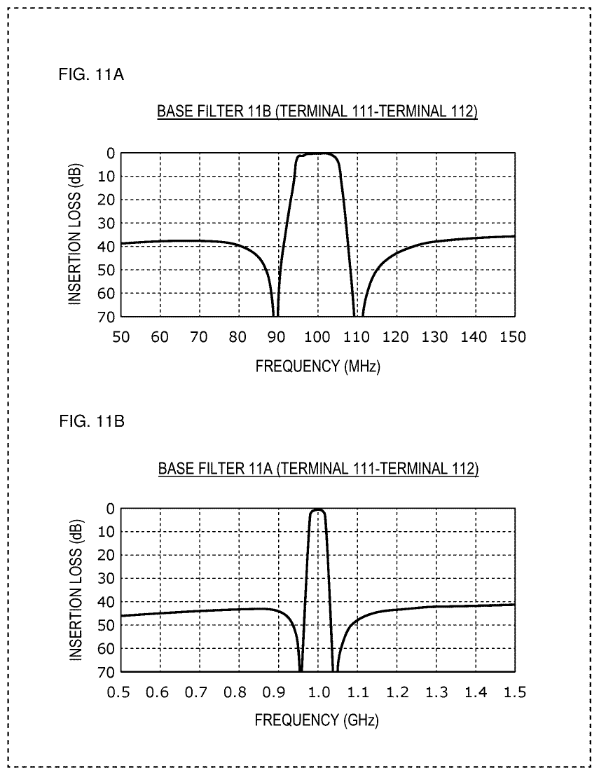

FIG. 10 is a diagram illustrating an example of the circuit configurations of the base filters 11B to 1NB according to the third example. An example of the circuit configuration of the base filter 11B, among the base filters 11B to 1NB, is illustrated in FIG. 10. The circuit configurations of the base filters 12B to 1NB are the same as the circuit configuration of the base filter 11B illustrated in FIG. 10.

As illustrated in FIG. 10, the base filter 11B includes acoustic wave resonators 66, 67, 68, 69, and 70. Each of the base filters 11B to 1NB according to the present example is a band pass filter including only the passive elements and includes the acoustic wave resonators.

The acoustic wave resonators 66 to 68 are series arm resonators connected in series between the terminal 111 and the terminal 112. The acoustic wave resonator 69 is a parallel arm resonator connected between a node on a path between the acoustic wave resonators 66 and 67 and the ground. The acoustic wave resonator 70 is a parallel arm resonator connected between a node on a path between the acoustic wave resonators 67 and 68 and the ground. With the above configuration, the base filter 11B illustrated in FIG. 10 is, for example, a ladder acoustic wave band pass filter.

FIG. 11A is a graph indicating a bandpass characteristic of the single base filter 11B according to the third example. FIG. 11B is a graph indicating a bandpass characteristic of the single base filter 11A according to the second example.

In the base filters 11B to 1NB according to the present example, each of the acoustic wave resonators 66 to 70 is a resonator using surface acoustic waves and uses, for example, a 15° rotated Y cut X SAW propagation LiNbO3 single crystal substrate (hereinafter referred to as LN) as a substrate having piezoelectricity. Each of the acoustic wave resonators 66 to 70 has a resonance band width (anti-resonant frequency-resonant frequency)/resonant frequency) of, for example, about 10%, and the resonant frequency (and the anti-resonant frequency) of the acoustic wave resonators 66, 68, and 70 is set to, for example a frequency about 12% higher than the resonant frequency (and the anti-resonant frequency) of the acoustic wave resonators 67 and 69. The impedance of the acoustic wave resonators 66 and 70 is, for example, about 4.12 times higher than the impedance of the acoustic wave resonators 67 and 69 and the impedance of the acoustic wave resonator 68 is, for example, about 8.24 times higher than the impedance of the acoustic wave resonators 67 and 69. The terminal impedance at the terminals 111 and 112 of the base filters 11B to 1NB is designed to be, for example, about 400 Ω.

Also in the N-path filter 1B according to the present example, when the terminal impedance at the input-output terminals 110 and 120 is denoted by Z₀ and the input-output impedance of the base filters 11B to 1NB is denoted by Zb, the reflection coefficient (Zb−N×Z₀)/(Zb+N×Z₀) desirably meets the relationship of Expression 2.

With the above configuration, since the return loss at the input-output terminals 110 and 120 is capable of being set to a value of, for example, less than about 10 dB, the mismatching loss with the external connection circuit connected to the input-output terminal 110 or 120 is capable of being reduced or prevented. Accordingly, the N-path filter 1B is applicable to a radio frequency front-end circuit that transmits the radio frequency signal with low loss.

As illustrated in FIG. 11A, for example, the base filter 11B is a band pass filter having a center frequency of about 100 MHz and a band width of about 10 MHz. As indicated in FIGS. 11A and 11B, since the base filter 11B according to the third example is a surface acoustic wave filter using the LN substrate, the base filter 11B according to the third example achieves the bandpass characteristic having a higher band width ratio (the passband/the center frequency), compared with that of the base filter 11A according to the second example.

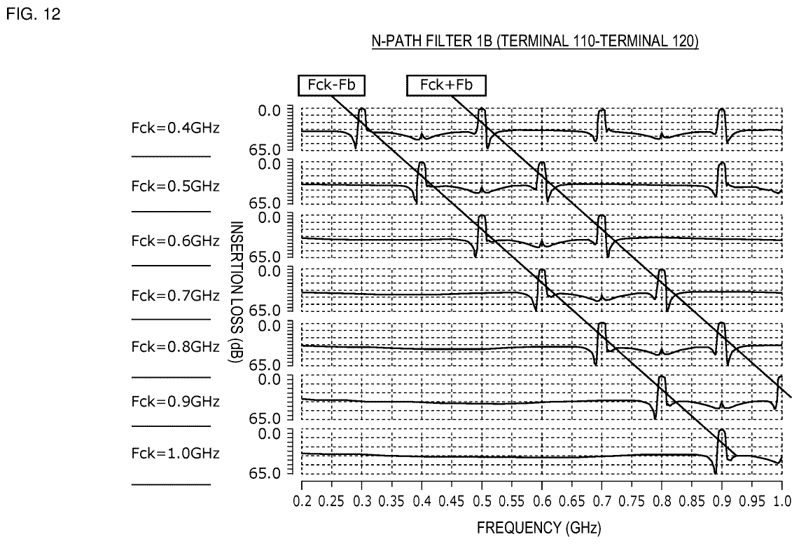

FIG. 12 is a graph indicating bandpass characteristics when the driving frequency Fck of the N-path filter 1B according to the third example is varied. The driving frequency Fck is varied within a range from about 0.4 GHz to about 1.0 GHz. As illustrated in FIG. 12, the passband of the N-path filter 1B appears at (k×Fck±Fb) in a frequency band range from DC to about 1.0 GHZ. Since a (Fck±Fb) (k=1) mode, among the (k×Fck±Fb) modes, is spaced apart from other harmonic waves, the N-path filter 1B has a waveform resulting from rough transcription of the waveforms of the base filters 11B to 1NB. Accordingly, the N-path filter 1B has the bandpass characteristics having a passband wider than that of the N-path filter 1A using the surface acoustic wave filter using the LT substrate and has the bandpass characteristics having attenuation steepness near the passband, which is higher than that of the N-path filter 1 using the LC filter, in a mode in which (Fck+Fb) (k=1) is a main response.

The base filter may be, for example, (1) a thin-film bulk acoustic wave filter using aluminum nitride (AlN) or scandium doped aluminum nitride (ScAlN) or (2) a bulk acoustic wave filter using piezoelectric single crystal, such as crystal, lithium tantalate, lithium niobate, or potassium niobate, or using a sintering shaped piezoelectric material, such as lead zirconate titanate or barium titanate, instead of the surface acoustic wave filter using the LT or the LN as the piezoelectric substrate, described in the second and third examples.

A longitudinally coupled filter using the acoustic wave resonators may be used as the base filter instead of the ladder filter using the acoustic wave resonators, for example.

A dielectric filter may be used as the base filter, instead of the LC filter and the acoustic wave filter described above, for example.

### 5. Variable Frequency Range when Main Response Mode is (Fck−Fb)

If an undesirable response overlapped with the main response exists in the N-path filter 1 (including the N-path filters 1A and 1B) according to the present example embodiment, the undesirable signal caused by the undesirable response is transmitted. It is preferable for the main response not to be overlapped with the undesirable response in the frequency in order not to transmit the undesirable signal.

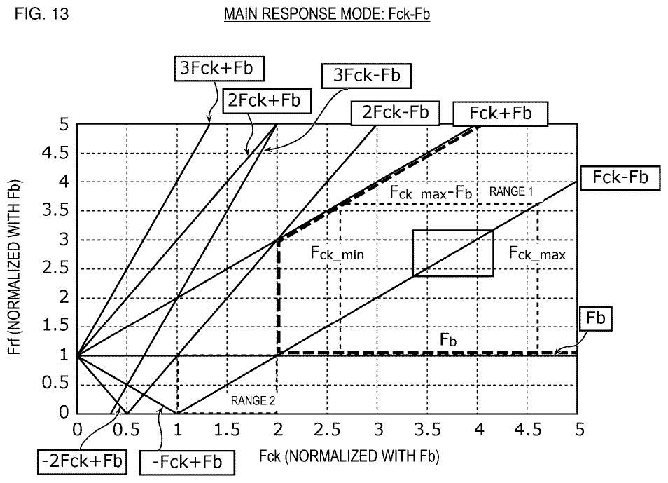

FIG. 13 is a graph indicating a variable frequency range when the main response mode of the N-path filter 1 according to the present example embodiment is (Fck−Fb). The graph indicated in FIG. 13 represents the relationship of Equation 1. The horizontal axis represents Fck (=Fck/Fb) normalized with Fb and the vertical axis represents Frf (=Frf/Fb) normalized with Fb. As illustrated in FIG. 13, varying the driving frequency Fck enables the center frequency Frf of the N-path filter 1 to be varied.

When any mode in (k×Fckt±−Fb) (k is an integer) is used as the main response in the N-path filter 1, the other modes are the undesirable responses. However, since an innumerable number of k exists, many undesirable response modes exist. In addition, since the N-path filter 1 uses the band pass filter as the base filter, the number of the undesirable responses occurring in the N-path filter 1 is about two times greater than that of an N-path filter using a low pass filter as the base filter. Furthermore, a case is considered in which the undesirable response existing at a negative frequency moves to a positive frequency to be overlapped with the main response at the driving frequency Fck around zero (0). Accordingly, when one main response mode is selected from the many modes, it is preferable to select a condition in which the main response mode is not overlapped with the undesirable response modes.

The response modes (0,1), (1,1), (1,−1), (2,1), (2,−1), (3,1), (3,−1), (−1,1), and (−2,1) are indicated in FIG. 13 as combinations of (Fck, Fb). Many modes of k<−3 and k>3 exist in a region in which the driving frequency Fck is at the low frequency side, although not indicated in FIG. 13.

When the main response mode is (Fck−Fb), the condition in which Frf in the main response mode (Fck−Fb) is not overlapped with Frf in the other undesirable response modes is represented by Range 1 (Expression 3) and Range 2 (Expression 4):

Range 1

Fck min+Fb>Fck_max−Fb and Fck>2Fb (Expression 3)

Range 2

1 Fb<Fck<2Fb (Expression 4)

Here, Fck min is the lower limit frequency of the driving frequency Fck in the main response mode and Fck max is the upper limit frequency of the driving frequency Fck in the main response mode.

As indicated in FIG. 13, in Range 1 and Range 2, the frequency of the main response mode is not overlapped with the frequencies of the undesirable response modes even if the frequency is varied. Accordingly, the low-loss passband having large attenuation and reduced broadened waveform in the continuous variable frequency range is achieved.

For example, a case is supposed in which the N-path filter 1 is subjected to the frequency variation within a frequency range from about 727 MHz to about 950 MHz that covers downlink operation bands of Bands n5, n8, n12, n14, n18, n20, n28, and n29 for the 5th Generation (5G)-New Radio (NR) and Bands B5, B8, B12, B13, B14, B17, B18, B19, B20, B26, B27, B28, B29, B67, B68, and B85 for the 4th Generation (4G)-Long Term Evolution (LTE). In this case, when (Fck−Fb) is selected as the main response mode and Fb=300 MHz, Fck min=about 1,027 MHz, and Fck max=about 1,250 MHz, the driving frequency Fck is in a frequency band in which the switches 21 to 2N and 31 to 3N are easily created using a complementary metal oxide semiconductor (CMOS) technology. In addition, the N-path filter 1 of the main response mode (Fck−Fb) the frequency of which is apart from those of (Fck+Fb) and (Fb), which are the closest undesirable response modes, is capable of being built. In this case, the normalized Fck (=Fck/Fb) is in a range from about 3.42 (=1,027 MHz/300 MHz) to about 4.17 (=1,250 MHz/300 MHz) and the normalized Frf (=Frf/Fb) is in a range from about 2.42 (=727 MHz/300 MHz) to about 3.17 (=950 MHz/300 MHZ).

The band applied to the N-path filter 1 means a frequency band that is defined in advance by a standardizing body or the like (for example, the 3rd Generation Partnership Project (3GPP (registered trademark)) or the Institute of Electrical and Electronics Engineers (IEEE)) for a communication system that is built using a Radio Access Technology (RAT). Although, for example, a 4th Generation (4G)-Long Term Evolution (LTE) system, a 5th Generation (5G)-New Radio (NR) system, a Wireless Local Area Network (WLAN) system, or the like is capable of being used as the communication system in the present example embodiment, the communication system is not limited to these systems.

### 6. Variable Frequency Range when Main Response Mode is (−Fck+Fb)

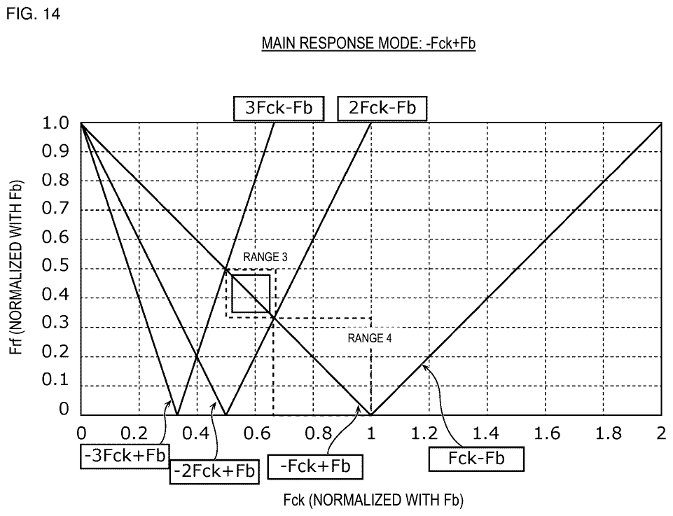

FIG. 14 is a graph indicating a variable frequency range when the main response mode of the N-path filter 1 according to the present example embodiment is (−Fck+Fb). The graph indicated in FIG. 14 represents the relationship of Equation 1. The horizontal axis represents Fck (=Fck/Fb) normalized with Fb and the vertical axis represents Frf (=Frf/Fb) normalized with Fb. As illustrated in FIG. 14, varying the driving frequency Fck enables the center frequency Frf of the N-path filter 1 to be varied.

The response modes (1,−1), (2,−1), (3,−1), (−1,1), (−2,1), and (−3,1) are indicated in FIG. 14 as combinations of (Fck, Fb).

When the main response mode is (−Fck+Fb), the condition in which Frf in the main response mode (−Fck+Fb) is not overlapped with Frf in the other undesirable response modes is represented by Range 3 (Expression 5) and Range 4 (Expression 6):

Range 3

0.5Fb<Fck<0.66Fb (Expression 5)

Range 4

0.67 Fb<Fck<1Fb (Expression 6)

As indicated in FIG. 14, in Range 3 and Range 4, the frequency of the main response mode is not overlapped with the frequencies of the undesirable response modes even if the frequency is varied. Accordingly, the low-loss passband having large attenuation and reduced broadened waveform in the continuous variable frequency range is achieved.

For example, in a case in which the N-path filter 1 is subjected the frequency variation within a frequency range from about 727 MHz to about 950 MHZ, when (−Fck+Fb) is selected as the main response mode, Fb=about 2,000 MHZ, and Fck is in a range from about 1,273 MHz to about 1, 050 MHz, the base filters 11 to 1N are capable of being provided in a high frequency range. Accordingly, when the LC filter or the acoustic wave filter is used as the base filter, it is possible to reduce the size of the N-path filter 1.

### 7. Variable Frequency Range when Main Response Mode is (2Fck−Fb)

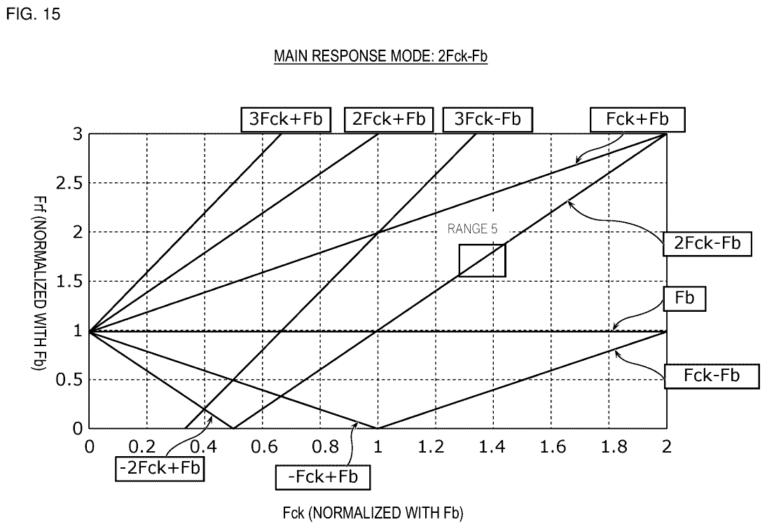

FIG. 15 is a graph indicating a variable frequency range when the main response mode of the N-path filter 1 according to the present example embodiment is (2Fck−Fb). The graph indicated in FIG. 15 represents the relationship of Equation 1. The horizontal axis represents Fck (=Fck/Fb) normalized with Fb and the vertical axis represents Frf (=Frf/Fb) normalized with Fb. As illustrated in FIG. 15, varying the driving frequency Fck enables the center frequency Frf of the N-path filter 1 to be varied.

The response modes (0,1), (1,1), (1,−1), (2,1), (2,−1), (3,1), (3,−1), (−1,1), and (−2,1) are indicated in FIG. 15 as an example of combinations of (Fck, Fb).

When the main response mode is (2Fck−Fb), the condition in which Frf in the main response mode (2Fck−Fb) is not overlapped with Frf in the other undesirable response modes is represented by Range 5 (Expression 7):

Range 5

Fck>1Fb and 2Fck ma−-Fb<Fck min+Fb (Expression 7)

Here, Fck min is the lower limit frequency of the driving frequency Fck in the main response mode and Fck max is the upper limit frequency of the driving frequency Fck in the main response mode.

As indicated as an example in FIG. 15, in Range 5, the frequency of the main response mode is not overlapped with the frequencies of the undesirable response modes even if the frequency is varied. Accordingly, the low-loss passband having large attenuation and reduced broadened waveform in the continuous variable frequency range is achieved.

For example, in a case in which the N-path filter 1 is subjected the frequency variation within a frequency range from about 727 MHz to about 950 MHz, when (2Fck−Fb) is selected as the main response mode, Fb=about 500 MHz, and Fck is in a range from about 613.5 MHz to about 725 MHz, the N-path filter 1 of the main response mode (2Fck−Fb) the frequency of which is sufficiently apart from those of (Fck+Fb) and (Fb), which are the closest undesirable response modes, is capable of being built.

### 8. Variable Frequency Range when Main Response Mode is (Fck+Fb)

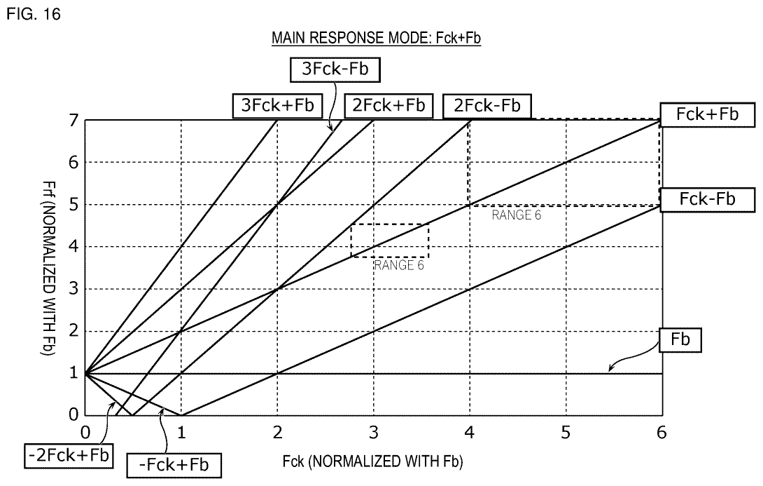

FIG. 16 is a graph indicating a variable frequency range when the main response mode of the N-path filter 1 according to the present example embodiment is (Fck+Fb). The graph indicated in FIG. 16 represents the relationship of Equation 1. The horizontal axis represents Fck (=Fck/Fb) normalized with Fb and the vertical axis represents Frf (=Frf/Fb) normalized with Fb. As illustrated in FIG. 16, varying the driving frequency Fck enables the center frequency Frf of the N-path filter 1 to be varied.

The response modes (0,1), (1,1), (1,−1), (2,1), (2,−1), (3,1), (3,−1), (−1,1), and (−2,1) are indicated in FIG. 16 as an example of combinations of (Fck, Fb).

When the main response mode is (Fck+Fb), the condition in which Frf in the main response mode (Fck+Fb) is not overlapped with Frf in the other undesirable response modes is represented by Range 6 (Expression 8):

Range 6

Fck>2Fb,

Fck max+Fb<2Fck min−Fb, and

Fck max−Fb<Fck min+Fb (Expression 8)

Here, Fck min is the lower limit frequency of the driving frequency Fck in the main response mode and Fck max is the upper limit frequency of the driving frequency Fck in the main response mode.

As indicated as an example in FIG. 16, in Range 6, the frequency of the main response mode is not overlapped with the frequencies of the undesirable response modes even if the frequency is varied. Accordingly, the low-loss passband having large attenuation and reduced broadened waveform in the continuous variable frequency range is achieved.

In the N-path filter 1 according to the present example embodiment, (k×Fck+Fb) (k is an integer) may be used as the main response mode. In the main response mode (k×Fck+Fb), since Frf is calculated from addition of the center frequency Fb of the base filters 11 to 1N to (an integral multiple of) the driving frequency Fck, it is possible to decrease the driving frequency Fck, compared with the N-path filter using a low pass filter as the base filter.

Using a semiconductor switch as the modulator in the N-path filter 1 having a high frequency band of, for example, about 10 GHz or more as the passband creates a problem in which there is no room in the response frequency of the switch or a circuit that generates a signal for driving the switch. However, with the above configuration, it is possible to decrease the driving frequency Fck to relieve the burden on the semiconductor switch and the driving signal generation circuit.

### 9. Circuit Configuration of Radio Frequency Module 5 and Communication Apparatus 10 according to Example Embodiment

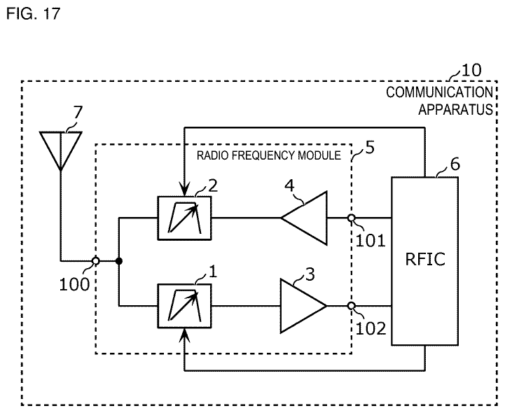

FIG. 17 is a diagram illustrating the circuit configuration of a radio frequency module 5 and a communication apparatus 10 according to an example embodiment of the present invention. As illustrated in FIG. 17, the communication apparatus 10 includes the radio frequency module 5, a radio frequency (RF) signal processing circuit (radio frequency integrated circuit (RFIC)) 6, and an antenna 7.

The radio frequency module 5 transmits the radio frequency signal between the antenna 7 and the RFIC 6. The antenna 7 is connected to an antenna connection terminal 100 of the radio frequency module 5. The radio frequency signal output from the radio frequency module 5 is transmitted through the antenna 7 and the radio frequency signal is received from the outside through the antenna 7 to be supplied to the radio frequency module 5.

The RFIC 6 is an example of a signal processing circuit that processes the radio frequency signal. Specifically, the RFIC 6 performs signal processing, such as down-conversion, for example, to a radio frequency reception signal input through a reception path of the radio frequency module 5 and supplies a reception signal resulting from the signal processing to a baseband signal processing circuit (baseband integrated circuit (BBIC)) (not illustrated). In addition, the RFIC 6 performs signal processing, such as up-conversion, for example, to a transmission signal supplied from the BBIC and supplies a radio frequency transmission signal resulting from the signal processing to a transmission path of the radio frequency module 5. Furthermore, the RFIC 6 includes a controller that controls the N-path filter 1 and an N-path filter 2, amplifiers, and so on in the radio frequency module 5. A portion or all of the functions of the RFIC 6 defining and functioning as the controller may be provided outside the RFIC 6. For example, a portion or all of the functions of the RFIC 6 defining and functioning as the controller may be provided in the BBIC or the radio frequency module 5.

In the communication apparatus 10 according to the present example embodiment, the antenna 7 is not an essential component.

Next, the circuit configuration of the radio frequency module 5 will be described. As illustrated in FIG. 17, the radio frequency module 5 includes the N-path filters 1 and 2, a power amplifier 4, a low-noise amplifier 3, the antenna connection terminal 100, a radio frequency input terminal 101, and a radio frequency output terminal 102.

The antenna connection terminal 100 is connected to the antenna 7. The radio frequency input terminal 101 is connected to the RFIC 6 and is a terminal to receive the radio frequency transmission signal from the RFIC 6. The radio frequency output terminal 102 is connected to the RFIC 6 and is a terminal to supply the radio frequency reception signal to the RFIC 6.

The N-path filter 1 is any of the N-path filter 1 according to the first example, the N-path filter 1A according to the second example, and the N-path filter 1B according to the third example and is a filter for reception connected between the antenna connection terminal 100 and the low-noise amplifier 3. The N-path filter 1 varies the passband and the attenuation band in response to the driving signals s1 to sN supplied from the RFIC 6. With this configuration, the N-path filter 1 is capable of selectively transmitting the radio frequency signals in the multiple bands.

The N-path filter 2 is any of the N-path filter 1 according to the first example, the N-path filter 1A according to the second example, and the N-path filter 1B according to the third example and is a filter for transmission connected between the antenna connection terminal 100 and the power amplifier 4. The N-path filter 2 varies the passband and the attenuation band in response to the driving signals s1 to sN supplied from the RFIC 6. With this configuration, the N-path filter 2 is capable of selectively transmitting the radio frequency signals in the multiple bands.

A driving circuit that outputs the driving signals s1 to sN may be included in the controller in the RFIC 6 or may be included in the radio frequency module 5. Alternatively, the driving circuit may be provided separately from the radio frequency module 5 and the RFIC 6 as a semiconductor integrated circuit (IC).

The low-noise amplifier 3 is connected between the N-path filter 1 and the radio frequency output terminal 102 and amplifies the reception signal supplied from the antenna connection terminal 100.

The power amplifier 4 is connected between the N-path filter 2 and the radio frequency input terminal 101 and amplifies the transmission signal supplied from the radio frequency input terminal 101.

With the above configuration, it is not necessary to provide the filters corresponding to the respective multiple bands and it is sufficient to dispose one N-path filter supporting the multiple bands. Accordingly, it is possible to reduce the sizes of the radio frequency module 5 and the communication apparatus 10.

The radio frequency module 5 and the communication apparatus 10 may include, for example, an impedance matching element, switches, and so on, in addition to the circuit elements illustrated in FIG. 17.

The radio frequency module 5 may include multiple power amplifiers and a switch for switching connection between any of the multiple power amplifier and the N-path filter 2. The radio frequency module 5 may include multiple low-noise amplifiers and a switch for switching connection between any of the multiple low-noise amplifiers and the N-path filter 1.

### Other Example Embodiments

Although the N-path filters according to the present invention are described using example embodiments, the present invention is not limited to the above-described example embodiments. Modifications resulting from making various modifications conceived by a person skilled in the art to the above-described example embodiments without departing from the sprit and scope of the present invention and various devices incorporating the N-path filter according to example embodiments of the present invention are also included in the present invention.

For example, in the N-path filters according to the example embodiments described above, matching elements, such as inductors and capacitors, and switch circuits may be connected between the respective components.

The band pass filter may be a passive filter in which, when an input-side switch of the N-path filter is turned on or off, a signal to be transmitted is subjected to zero-order hold until the next turning-off or turning-on.

Even if a parasitic inductor component, such as, for example, wiring or a wire, exists between an input-side switch and the base filter, the influence on the impedance of the base filter is low. Accordingly, the influence of the parasitic inductor component on the impedance of the base filter may be ignored.

Example embodiments of the present invention are widely usable for a communication device, such as, for example, a mobile phone, as a filter with low loss and high attenuation which is applicable to multiband and multimode frequency standards.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An N-path filter comprising:
a first input-output terminal and a second input-output terminal; and
N-number signal paths connected in parallel to each other between the first input-output terminal and the second input-output terminal, N being an integer not less than three; wherein
each of the N-number signal paths includes:
a first modulator connected to the first input-output terminal to modulate an input signal supplied from the first input-output terminal or the second input-output terminal;
a second modulator connected to the second input-output terminal to modulate the input signal in the same phase as that of the first modulator; and
a base filter connected between the first modulator and the second modulator;
the first modulator and the second modulator are operable to modulate the input signal in a phase of one period defined by different phases of the different N-number signal paths; and
the base filter includes a band pass filter including only passive elements.

2. The N-path filter according to claim 1, wherein
the first modulator includes a first switch to switch between connection and non-connection between the first input-output terminal and the base filter in response to a driving signal; and
the second modulator includes a second switch to switch between connection and non-connection between the second input-output terminal and the base filter at the same timing as that of the first switch in response to the driving signal.

3. The N-path filter according to claim 1, wherein, when a driving frequency of the first modulator and the second modulator is denoted by Fck, a center frequency in a passband of the single base filter is denoted by Fb, a center frequency in the passband in a main response mode of the N-path filter is denoted by (Fck−Fb), a maximum driving frequency at which the main response mode is available is donated by Fck max, and a minimum driving frequency at which the main response mode is available is denoted by Fck min, the relationships Fck min+Fb>Fck max-Fb and Fck>2Fb are satisfied.

4. The N-path filter according to claim 1, wherein, when a driving frequency of the first modulator and the second modulator is denoted by Fck, a center frequency in a passband of the single base filter is denoted by Fb, and a center frequency in the passband in a main response mode of the N-path filter is denoted by (Fck−Fb), the relationship 1Fb<Fck<2Fb is satisfied.

5. The N-path filter according to claim 1, wherein, when a driving frequency of the first modulator and the second modulator is denoted by Fck, a center frequency in a passband of the single base filter is denoted by Fb, and a center frequency in the passband in a main response mode of the N-path filter is denoted by (−Fck+Fb), the relationship 0.5Fb<Fck<0.66Fb is satisfied.

6. The N-path filter according to claim 1, wherein, when a driving frequency of the first modulator and the second modulator is denoted by Fck, a center frequency in a passband of the single base filter is denoted by Fb, and a center frequency in the passband in a main response mode of the N-path filter is denoted by (−Fck+Fb), the relationship 0.67 Fb<Fck<1Fb is satisfied.

7. The N-path filter according to claim 1, wherein, when a driving frequency of the first modulator and the second modulator is denoted by Fck, a center frequency in a passband of the single base filter is denoted by Fb, and a center frequency in the passband in a main response mode of the N-path filter is denoted by (2Fck−Fb), the relationships Fck>1Fb and 2Fck max−Fb<Fck min+Fb are satisfied.

8. The N-path filter according to claim 1, wherein, when a driving frequency of the first modulator and the second modulator is denoted by Fck, a center frequency in a passband of the single base filter is denoted by Fb, and a center frequency in the passband in a main response mode of the N-path filter is denoted by (Fck+Fb), the relationships Fck>2Fb, Fck max+Fb<2Fck min−Fb, and Fck max−Fb<Fck min+Fb are satisfied.

9. The N-path filter according to claim 1, wherein the base filter includes an inductor and a capacitor.

10. The N-path filter according to claim 9, wherein, when a driving frequency of the first modulator and the second modulator is denoted by Fck and a center frequency in a passband of the single base filter is denoted by Fb, a center frequency in the passband in a main response mode of the N-path filter is (k×Fck+Fb), where k is an integer.

11. The N-path filter according to claim 1, wherein the base filter is an acoustic wave filter.

12. The N-path filter according to claim 1, wherein, when a terminal impedance of the N-path filter is denoted by Z₀ and an input-output impedance of the base filter is denoted by Zb, the relationship (Zb−N×Z₀)/(Zb+N×Z₀)<0.316 is satisfied.

13. The N-path filter according to claim 1, wherein the base filter is a band pass filter including a capacitor connected in parallel to an input-side switch of the N-path filter.

14. The N-path filter according to claim 1, wherein the base filter is a band pass filter including an acoustic wave element connected to an input-side switch of the N-path filter.

15. The N-path filter according to claim 1, wherein the base filter is a band pass filter including no series inductor connected to an input-side switch of the N-path.
